(19) United States
(12) Patent Application Publication
(10) Pub. No.: US 2010/0034621 A1
(43) Pub. Date: Feb. 11, 2010

(54) END EFFECTOR TO SUBSTRATE OFFSET DETECTION AND CORRECTION

(76) Inventors: Raymond S. Martin, Fremont, CA (US); Anthony C. Bonora, Fremont, CA (US); Michael Krolak, Fremont, CA (US)

Correspondence Address: MARTINE PENILLA & GENCARELLA, LLP, 710 LAKEWAY DRIVE, SUITE 200, SUNNYVALE, CA, 94085, US

(21) Appl. No.: 12/432,359

(22) Filed: Apr. 29, 2009

Related U.S. Application Data
(60) Provisional application No. 61/049,387, filed on Apr. 30, 2008.

(51) Int. Cl. H01L 21/677

(52) U.S. Cl. 414/217.1

(57) ABSTRACT

A port door providing an interface into a processing tool is provided. The port door includes first and second arms pivotably mounted on a top edge of the port door. The first and second arms are configured to extend from a plane of the port door towards a carrier containing substrates for the processing tool. The first arm has an emitter transmitting a beam that is split into a plurality of sub-beams within the first arm. The second arm has a plurality of sensors receiving corresponding sub-beams, wherein one of sub-beams provides information as to a position of an end effector relative to a gap between the substrates in the carrier.

### CROSS REFERENCE TO RELATED APPLICATIONS

This application claims priority from U.S. Provisional Patent Application No. 61/049,387 filed Apr. 30, 2008 and entitled “End Effector Having Sensing Capability.” This provisional application is herein incorporated by reference.

### BACKGROUND

The manufacturing of semiconductor components relies on automation for yield and cleanliness purposes. The transfer of substrates to and from front opening unified pods (FOUPs) and process tools is one area where losses can take place in the form of damage to the substrates or damage to the end effectors moving the substrates. Current systems are unable to determine the relative location of the substrates to be transferred and the end effector providing the transfer mechanism. Thus, there is no mechanism to determine whether the end effector has the proper clearance to insert or remove substrates from the carrier or front opening unified pod. Consequently, the substrates can be scratched, damaged, or destroyed by the end effector depending on the severity of any collision between the end effector and the substrate. As the end effectors move into the carriers at rapid velocities and high acceleration, the potential for damage is great for instances where there is misalignment between the end effector and the substrate. The clearance for the end effector is typically +/−4 millimeters, which does not leave much room for error. For an edge gripping end effector the clearance can be reduced to =/−3.5 millimeters. This clearance must account for substrate position errors, substrate flatness, and other mechanical tolerances. Additionally, when one substrate is destroyed, the damage can be translated to all the substrates in the carrier.

In addition, gathering information on the orientation of the semiconductor wafer being transported from or to a container such as a Front Opening Unified Pod (FOUP) is becoming more desirable. As wafer diameters increase to 450 millimeters, the additional information on the wafer being transported will aid the transport process.

Accordingly, improvements are needed in order to detect any possible misalignment and prevent damage to the substrates. In addition, it would be beneficial to be able to analyze the position/orientation of the wafers in the container to determine offsets or calibrate the position of the transporting device for obtaining or dropping off the wafer.

### SUMMARY

Embodiments of the present invention provide methods and systems for transferring a substrate to and from a substrate container. It should be appreciated that the present invention can be implemented in numerous ways, such as a process, an apparatus, a system, a device or a method on a computer readable medium. Several inventive embodiments of the present invention are described below.

In one embodiment, a port door providing an interface into a processing tool is provided. The port door includes first and second arms pivotably mounted on a top edge of the port door. The first and second arms are configured to extend from a plane of the port door towards a carrier containing substrates for the processing tool. The first arm has an emitter transmitting a beam that is split into a plurality of sub-beams within the first arm. The second arm has a plurality of sensors receiving corresponding sub-beams, wherein one of sub-beams provides information as to a position of an end effector relative to a gap between the substrates in the carrier.

In another embodiment, a method for transferring a substrate from a carrier is provided. The method includes positioning the carrier onto a carrier interface of a processing tool. A door of the processing tool is transitioned to allow transfer of the substrate. The transitioning includes, pivoting a first and a second extension toward the carrier; generating a beam from an emitter disposed within the first extension; splitting the beam into multiple sub-beams; and redirecting each sub-beam toward the second extension. The method further includes positioning an end effector to transfer a substrate from the carrier. A position of the end effector relative to a position of the substrate is determined through first and second sub-beams. The position of the end effector is adjusted when the position of the end effector the position of the substrate coincide.

Other aspects of the invention will become apparent from the following detailed description, taken in conjunction with the accompanying drawings, illustrating by way of example the principles of the invention.

### BRIEF DESCRIPTION OF THE DRAWINGS

The invention may best be understood by reference to the following description taken in conjunction with the accompanying drawings in which:

FIG. 1 is a simplified schematic diagram of a door mechanism of a load port which is used to remove carrier doors and contain a substrate mapper in accordance with one embodiment of the invention.

FIG. 2 is a simplified schematic diagram illustrating the utilization of multiple beams of illumination for detection of a substrate and end effector from the same mechanical reference point in accordance with one embodiment of the invention.

FIG. 3 is a simplified schematic diagram illustrating further details of an emitter assembly in accordance with one embodiment of the invention.

FIG. 4 is a simplified schematic diagram illustrating the sensor assembly receiving the emitted beams in accordance with one embodiment of the invention.

FIG. 5 is a simplified schematic diagram illustrating the reduction of the emitted beam in accordance with one embodiment of the invention.

FIG. 6 is a simplified schematic diagram illustrating an alternative embodiment for the detection of the emitted beam through a retro reflector in accordance with one embodiment of the invention.

FIG. 7 is a simplified schematic diagram illustrating an arm having both an emitter and sensor capability in accordance with one embodiment of the invention.

FIG. 8 is a more detailed view of the beam splitter and sensor assembly illustrated in FIG. 7.

FIG. 9 is a flow chart diagram illustrating the method operations for determining the end effector top and bottom surfaces in the Z direction in accordance with one embodiment of the invention.

FIGS. 10A and 10B illustrate the detection of a protruding substrate from the substrate carrier in accordance with one embodiment of the invention.

FIG. 11 is a simplified schematic diagram illustrating an alternative emitter assembly for the detection system in accordance with one embodiment of the invention.

FIG. 12 is a simplified schematic diagram illustrating an illumination source that generates a plane of illumination in accordance with one embodiment of the invention.

FIG. 13 is another embodiment that has the End Effector emitter and sensor mounted directly on the door assembly.

FIG. 14 is a simplified schematic diagram illustrating an external end effector having sensing capabilities according to one embodiment of the invention.

FIG. 15A is a simplified schematic diagram illustrating the end effector with sensing capabilities in accordance with one embodiment of the invention.

FIG. 15B is a simplified schematic diagram of a side view of the end effector in accordance with one embodiment of the invention.

FIGS. 15C and 15D are simplified schematic diagrams illustrating the end effector positioned at different locations relative to the wafers to generate different positional information in accordance with one embodiment of the invention.

FIG. 15E is a simplified schematic diagram of utilization of the sensing capability of the end effector to determine a position of the center of the substrate in accordance one embodiment of the invention.

FIG. 16 is a simplified schematic diagram illustrating alternative versions of the end effector with sensing capabilities in accordance with one embodiment of the invention.

FIG. 17 is a simplified schematic diagram illustrating a perspective view of the end effector in accordance with one embodiment of the invention.

FIG. 18 is a simplified schematic diagram of the end effector with the pivoted supports actuated in accordance with one embodiment of the invention.

FIG. 19 is a simplified schematic diagram showing further details on the pivotable mechanism triggered in order to actuate support stops 102a and 102b.

FIG. 20 is a simplified schematic diagram illustrating an end effector having sensing capabilities in accordance with one embodiment of the invention.

FIG. 21 illustrates end effector 100 moved into position around wafer 106 in accordance with one embodiment of the invention.

FIG. 22 illustrates end effector 100 having actuated support stops 102a and 102b.

FIG. 23 is a simplified schematic diagram illustrating the end effector in position with an empty FOUP in accordance with one embodiment of the invention.

FIG. 24 illustrates a simplified schematic diagram of an internal end effector having sensing capabilities in accordance of one embodiment of the invention.

FIGS. 25A and 25B illustrate an internal end effector and corresponding FOUP with the end effector prior to entry into the FOUP in FIG. 25A and inserted into the FOUP in FIG. 25B.

FIG. 26 is a simplified schematic diagram of an alternative embodiment for an internal end effector sensing capability.

FIG. 27 is a simplified schematic diagram of the use of image capture devices providing the sensing capabilities of the end effector in accordance with one embodiment of the invention.

### DETAILED DESCRIPTION

Methods and systems for delivering and accessing substrates from a substrate container are provided. It will be obvious, however, to one skilled in the art, that the present invention may be practiced without some or all of these specific details. In other instances, well known process operations have not been described in detail in order not to unnecessarily obscure the present invention.

Wafer mapper technology, as visible in the load port or equipment front end module provides the ability to map the presence or absence of a substrate and the ability to detect double stacked substrates, i.e., two substrates in one slot. In addition, the ability to identify cross substrates, i.e., a substrate which is in one shelf on the left side of a front opening unified pod (FOUP) and a different shelf on the right side, is able to be identified. However, the wafer mapper technology does not precisely determine the location of the substrate top surface and the substrate bottom surface for each of the substrates or potential substrates in a FOUP. Furthermore, no provision is provided to determine the top and bottom surfaces of the end effector. The embodiments described below provide information on the relative location of the end effector and the substrates so that if the position of the substrate and the end effector coincide, i.e., are such that a collision or scraping may occur, the position of the end effector may be adjusted or the process can be stopped prior to any damage occurring.

The process of inserting or removing substrates from a carrier typically involves the use of a mechanism containing an end effector which is inserted into the carrier. The end effector is attached to the substrate through a variety of techniques, e.g., vacuum, edge grip, etc. The end effector then withdraws the substrate from the carrier to deliver the substrate to a destination. The process is reversed to deposit a substrate into the carrier. Typical examples of a substrate include wafers, discs, flat panels, etc. Typical examples of a carrier include a rack, cage, collection of bins, FOUP, etc. The embodiments described below determine whether a position in a carrier has a substrate through a substrate mapping technique. The technique utilizes a beam of radiation, e.g., focus light, laser beam, etc., to make a decision on whether a substrate is present or absent from a position, as well as determine whether the location of an end effector is appropriate for avoiding any collisions with substrates.

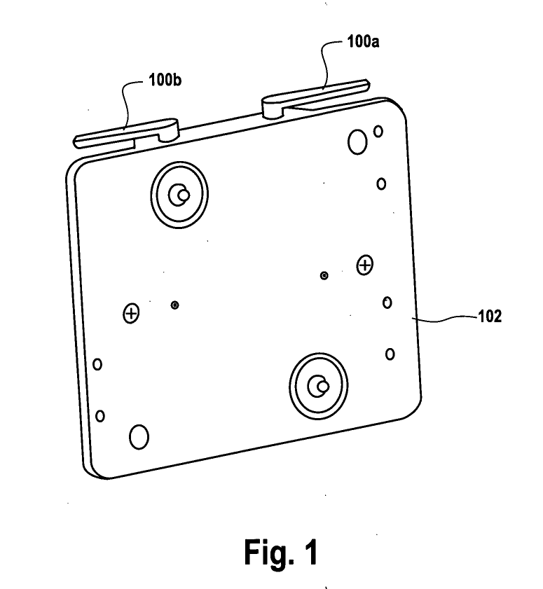

FIG. 1 is a simplified schematic diagram of a door mechanism of a load port which is used to remove carrier doors and contain a substrate mapper in accordance with one embodiment of the invention. In one embodiment, the mapper is a set of arms 100a and 100b, wherein one of the arms contain an emitter assembly, while the other arm contains a detector assembly. Arms 100a and 100b of door 102 flip or pivot toward the carrier area and scan the substrates as the door mechanism for the carrier door move door 102 in the minus Z direction. It should be appreciated that the Z direction is defined normal to the substrate surface to be processed. That is, is substantially parallel to a vertical axis of the substrates in the substrate carrier in one embodiment. One skilled in the art will appreciate that the pivot mechanism may include any known pivot joints. In addition, the pivot mechanism may include a spring loaded mechanism for extension and retraction of arms 100a and 100b.

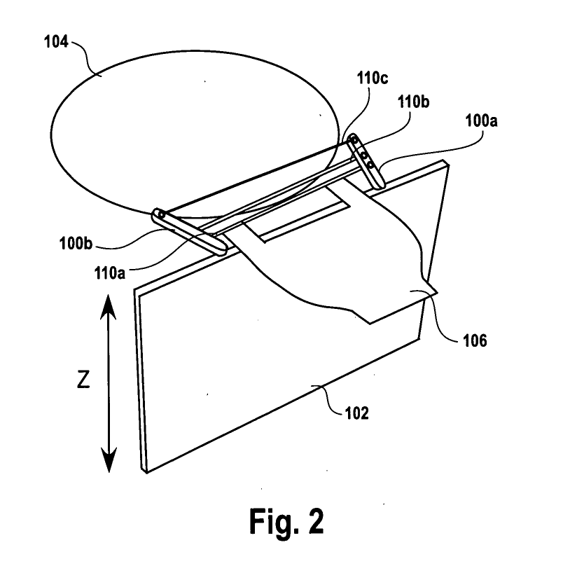

FIG. 2 is a simplified schematic diagram illustrating the utilization of multiple beams of illumination for detection of a substrate and end effector from the same mechanical reference point in accordance with one embodiment of the invention. Door 102 is capable of moving in the Z direction. End effector 106 will move into and out of a substrate container in order to transport substrate 104. Door 102 includes pivotable arms 100a and 100b. One of arms 100a and 100b functions as an emitter, while the other arm functions as a receiver/sensor in one embodiment. In alternative embodiments, the emitter and sensor are contained on the same arm or on a top edge of door 102. Three beams of illumination 110a through 110c are provided from the emitters to the receivers on arms 100a and 100b. Through the embodiments described herein, and the detection of the substrate and end effector from the same mechanical reference point, offsets between the substrate and the end effector can be determined. It should be appreciated that with this offset information, the end effectors position in the Z direction can be corrected to reduce the probability of scratching or damage to substrates in the carrier. Arms 100a and 100b can be retracted into the plane of door 102 or flipped into the region of a carrier containing one or more substrates 104.

It should be noted that FIG. 2, for illustrative purposes, does not illustrate the substrate carrier and shows one wafer that is suspended in the location of a slot of the carrier. End effector 106 is illustrated in a position over a top edge of door 102. End effector 106 breaks beam 110a, which is closest to the plane of the door as the door mechanism is moved in the minus Z direction. This permits detection of a top surface and bottom surface of the end effector in the Z direction. Beam 110b is used to detect substrate protrusion. That is, when a substrate is not properly seated in the carrier, the act of moving door 102 back to its starting position at the maximum Z height may result in a collision with the protruding substrate, thereby causing damage to one or more substrates in the carrier. Outer beam 110c is used to determine the position of the top and bottom surfaces of each substrate in the corresponding container. It should be appreciated that a computing system or controller communicatively coupled to the emitters, sensors, as well as the drive for end effector 106 and the mechanism moving door 102, can process the signals transmitted from the emitters and sensors to provide location information of the end effector relative to the substrates in the substrate container. This location information can be used to avoid collisions by halting a process or adjusting a vertical location of end effector 106. The computing system can store the appropriate information concerning the clearances required. The embodiments described herein provide for a common frame of reference based on the Z direction movement of door 102. The multiple beams of arm extensions 100a and 100b provide positional information on the top and bottom surface locations for substrate 104 and end effector 106.

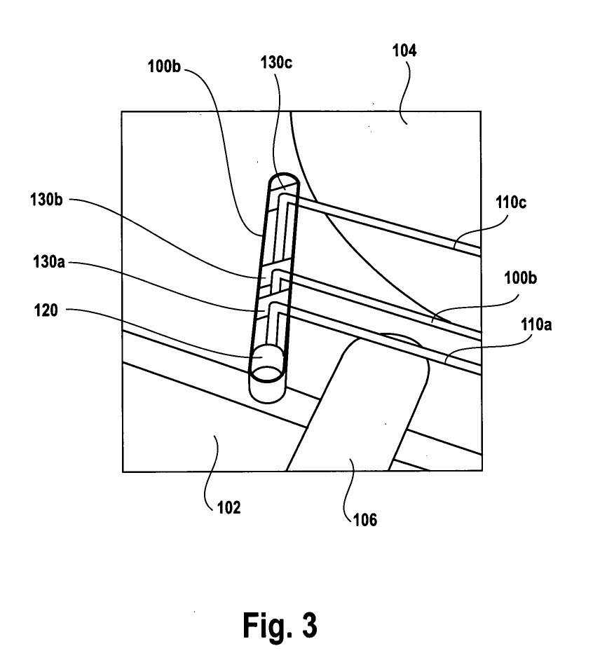

FIG. 3 is a simplified schematic diagram illustrating further details of an emitter assembly in accordance with one embodiment of the invention. Arm 100b includes an emitter assembly disposed therein. The emitter assembly is pivotably mounted within arm 100b on door 102. Emitter 120 can use either a focused light source, a laser source, or some other suitable radiation source that provides for detection of the substrate or end effector. Emitter 120 generates a beam of radiation towards mirrors 130a through 130c. Mirror 130a redirects a portion of the beam or illumination to beam 110a. It should be appreciated that mirror 130a is a semitransparent mirror in which part of the illumination is redirected onto the path of beam 110a while the remainder of the illumination proceeds through mirror 130a to mirror 130b. Mirror 130b is also a semitransparent mirror in which a portion of the beam transmitted through mirror 130a is redirected onto a path of beam 110b, while the remaining portion proceeds through to mirror 130c. The portion which continues through to mirror 130c is redirected onto the path illustrated by beam 110c. One skilled in the art will appreciate that more than three sub-beams 110a-c may be generated depending on the application and the illustration of three sub-beams is not meant to be limiting.

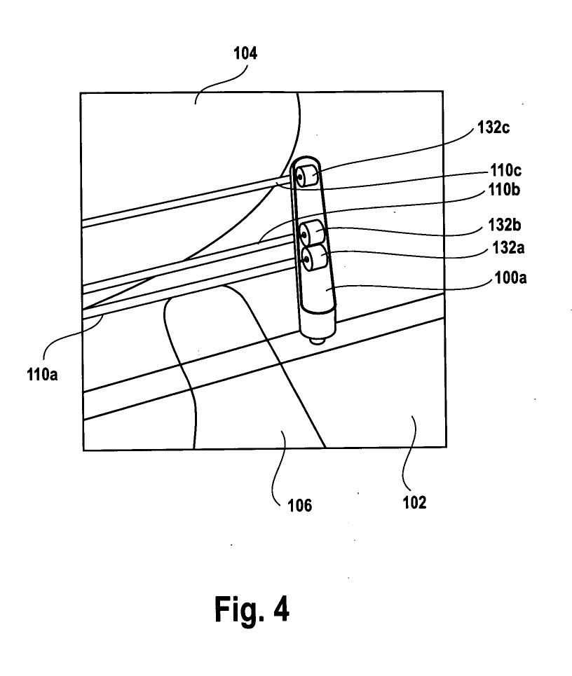

FIG. 4 is a simplified schematic diagram illustrating the sensor assembly receiving the emitted beams in accordance with one embodiment of the invention. Arm 100a is pivotably mounted on a top surface of door 102. Arm 100a includes a sensor assembly having sensors 132a through 132c. Sensors 132a through 132c of the sensor assembly capture beams traveling from the emitter assembly of FIG. 3. Thus, the beam from 110a is received by sensor 132a, the beam from 110b is received by sensor 132b, and the beam from 110c is received by sensor 132c. It should be appreciated that the corresponding beams may pass through a band pass filter whose pass band is in the wavelength of the emitters illumination, to reduce the affect of ambient illumination on the sensor. In addition, the beam may also pass through an aperture that is used to improve the spatial resolution of detection of substrate 104 or end effector 106. One skilled in the art will appreciate that sensors 132a through 132c can be any device capable of detecting the emitted radiation. Exemplary detectors include a photodiode, phototransistor, PIN diode, light dependent resistor, solar cell, charged couple device, hole accumulation diode (HAD) sensor, pyro-electric sensor, etc. Furthermore, the configuration of sensors 132a through 132c can be a single device, multiple devices, a linear array device, or a multi-axis array device. In one embodiment, each beam is reduced via a pin-hole aperture located in front of detectors 132a through 132c, in the wall of arm 100a, or somewhere in front of arm 100a. Accordingly, each beam will then impinge on the appropriately located detector 132a through 132c.

One skilled in the art will appreciate that the size of the pin hole aperture, the rate of movement of the scanning mechanism, and the response time of the electronics determine the dimensional resolution possible for this mechanism. In other embodiments, sensor linear rays, e.g., CCD line sensor arrays, replace the pin hole and detector are replaced to provide further improved resolution in position. In an alternative embodiment, a sensor two-dimensional array can be used. The second dimension in the plane of the substrate can provide additional sensing area and thus improve the signal-to-noise ratio. Additionally, a trade off in signal strength and resolution can be made to improve the positional resolution at the expense of a weaker signal and thus degraded signal-to-noise ratio, or vice versa.

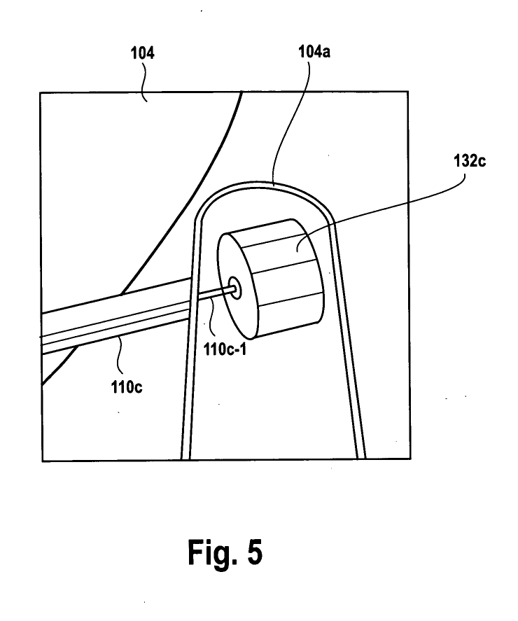

FIG. 5 is a simplified schematic diagram illustrating the reduction of the emitted beam in accordance with one embodiment of the invention. It should be appreciated that beam 110c may have some divergence and beam reduced in size through an aperture located on arm 100a improves the positional resolution. A pin hole aperture located on arm 100a will reduce the size of beam 110c as illustrated by beam 110c-1. The reduced beam diameter and reduced total energy of beam 110c-1 will impinge on detector 132c.

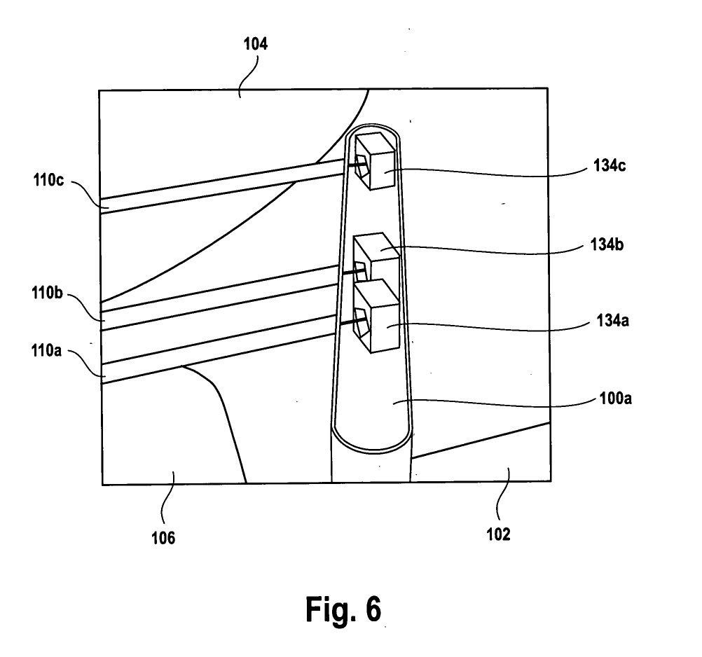

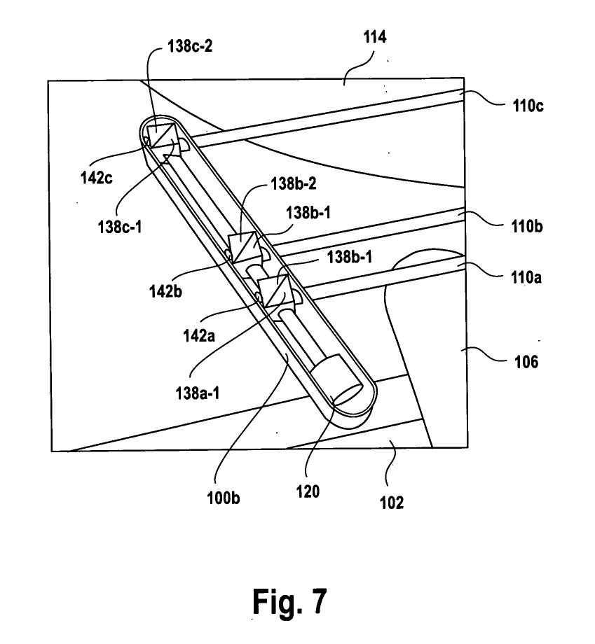

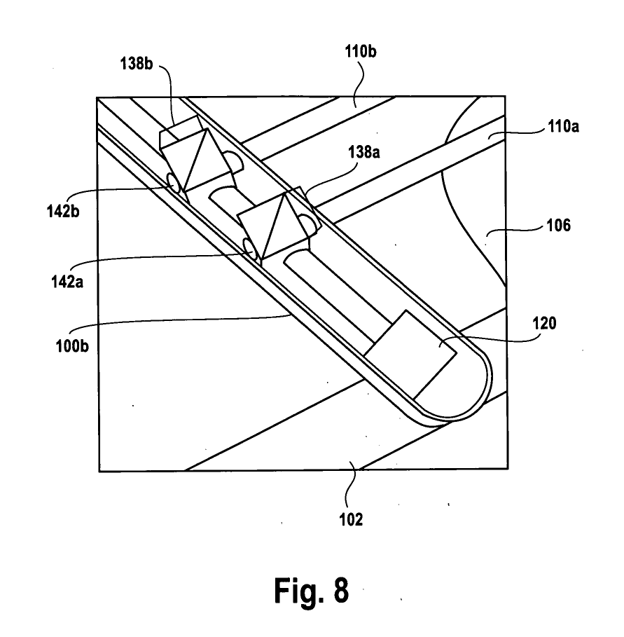

FIG. 6 is a simplified schematic diagram illustrating an alternative embodiment for the detection of the emitted beam through a retro reflector in accordance with one embodiment of the invention. Retro reflectors 134a through 134c are used to direct the corresponding emitted beam 110a through 110c back to the emitter assembly. One skilled in the art will appreciate that retroreflectors 134a through 134c can be a corner cube, reflective tape, or a simple mirror. A corner cube has the advantage of not requiring precision alignment to direct the beam back on the same path. This embodiment of FIG. 6 also has the advantage the no electronics or cables are required in arm 100a or external to arm 100a. In order for the embodiment of the retroreflector of FIG. 6 to function, the emitter arm is modified to contain both an emitter and a sensor, as further described with reference to FIGS. 7 and 8.

FIG. 7 is a simplified schematic diagram illustrating an arm having both an emitter and sensor capability in accordance with one embodiment of the invention. Arm 100b includes three beam splitter/detector units. The beam splitter/detector units can function both as a beam splitter and a detector. Each of the beam splitter/detector units includes a beam splitter 138a-1 through 138c-1 and detector 138a-2 through 138c-2. It should be appreciated that emitter 120 produces a beam which enters the face of an optical cube. As the beam hits the interfaces between the two prisms, a portion of the beam is reflected resulting in the beam traveling to the other arm, while the other portion passes therethrough. The portion passing through will travel to the next beam splitter and a portion of that beam will be reflected while the remaining portion will pass through to the final beam splitter 138c-1. The reflected beam from the retroreflector of FIG. 6 enters the cube and a portion of this is reflected back to the emitter 120. The remaining portion of the beam exits the cube and impinges on a sensor at the back of each cube. Sensors 142a through 142c provide the sensing for the reflected back portions of beams 110a through 110c, respectively.

FIG. 8 is a more detailed view of the beam splitter and sensor assembly illustrated in FIG. 7. Arm 100b is pivotably mounted on a top edge of door 102. Within arm 100b emitter 120 is disposed. Emitter 140 emits a beam of light to optical cube 138a of which a portion is reflected for beam 110a and a remaining portion passes through to optical cube 138b. Optical cube 138b similarly reflects a portion onto beam 110b while the remaining portion passes therethrough. Reflected beams from beams 110a and 110b are received by optical cubes 138a and 138b, respectively. Sensors 142a and 142b receive the necessary signals to determine locations and offsets as described above. It should be appreciated that in alternate embodiments the sensors may be replaced with a band pass filter and sensor. These may be optically cemented together and mounted on the beam splitter cube, with a filter providing improved immunity to ambient light.

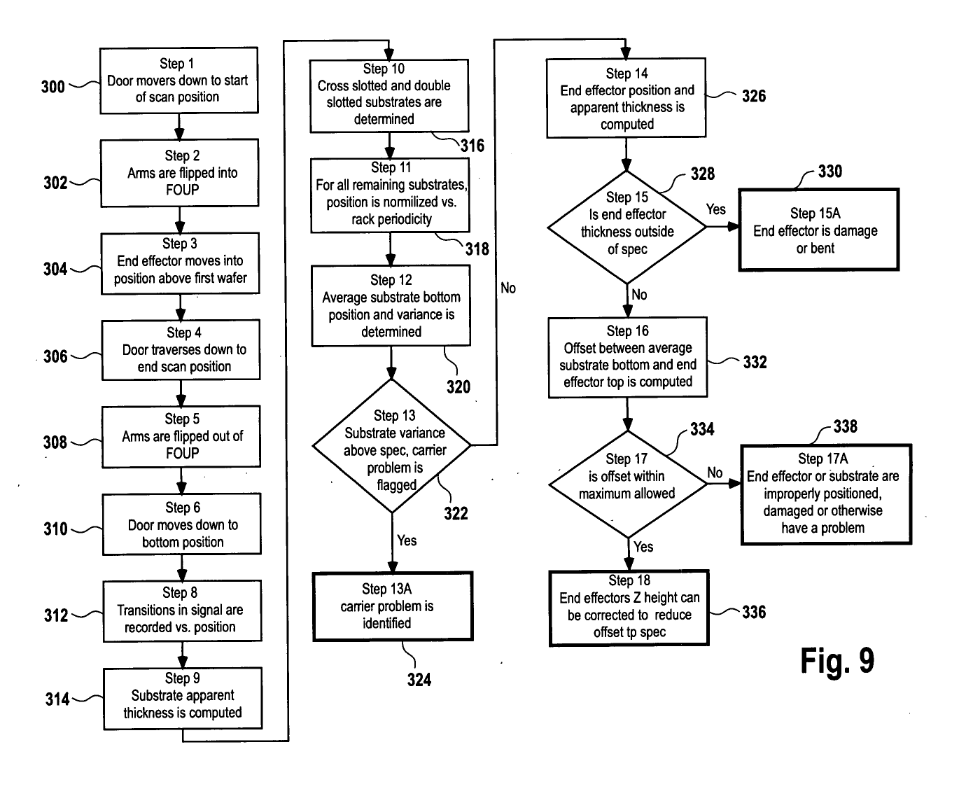

FIG. 9 is a flow chart diagram illustrating the method operations for determining the end effector top and bottom surfaces in the Z direction in accordance with one embodiment of the invention. FIG. 9 initiates with operation 300 where a port door/interface to a load port moves down to start a scan position. The method then advances to operation 902 where the arms or extensions are flipped or pivoted toward the FOUP. In operation 304, the end effector moves into position to obtain a first wafer. The method then advances to operation 306 where the door traverses down to an end of scan position. In operation 308, the arms are flipped out of the FOUP. The door then moves down to a bottom position in operation 310. In operation 312, transitioning signals are recorded versus the position. Then, in operation 314, the substrate thickness is computed. The method then advances to operation 316 where any cross slotted or double slotted substrates are identified. In operation 318, all remaining substrates have their position normalized versus a rack periodicity. The method then proceeds to operation 320 where the average substrate bottom position and variance is determined.

In decision operation 322 of FIG. 9, it is determined if the substrate variance is above the specifications provided by the carrier. If the substrate variance is above the specification, the method proceeds to operation 324 where the carrier is identified as a problem. If the substrate variance is not above the specifications for the carrier, the method advances to operation 326 where the end effector position and apparent thickness is computed. Here, the beam broken by the end effector is used to provide the position and thickness. In decision operation 328 it is determined if the end effector thickness is outside of the specification. If the end effector thickness is outside of the specification, the method proceeds to operation 330 where the end effector is identified as damaged or bent. If the end effector thickness is not outside of the specification in operation 28, the method advances to operation 332 where the offset between the average substrate bottom and end effector top is computed.

The method of FIG. 9 then moves to operation 334 where it is determined if the offset is within the maximum allowed. If the offset is not within the maximum allowed, the method proceeds to operation 338 where the end effectors or substrates are identified as being improperly positioned, damaged, or have other problems which prevent proceeding. If the offset is within the limits, then the method proceeds to operation 336 where the end effectors Z height can be corrected to reduce offset to any specification, if necessary. Once the end effector height/position is adjusted, if necessary, the end effector obtains the substrate from the substrate carrier. It should be appreciated that the information for the remainder of the substrates can be stored and reused as the end effector is only changing positions. Thus, once the end effector returns for another substrate, the positional information for the end effector is recalculated based on the sensor signals provided through the Z movement of the port door. It should be noted that the data collected through the embodiments described herein may also be utilized for statistical process control purposes.

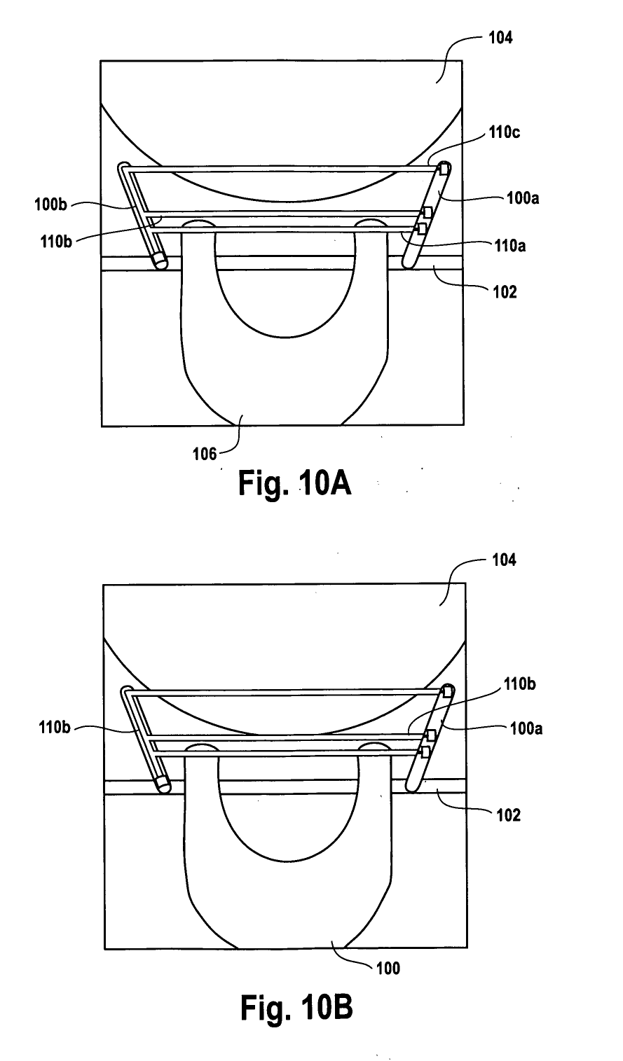

FIGS. 10A and 10B illustrate the detection of a protruding substrate from the substrate carrier in accordance with one embodiment of the invention. When a substrate is not properly inserted into the substrate carrier, the substrate may extend out so as to interfere with the operation of other mechanisms or the door of the substrate container. This interference may result in damage to the substrate. Sub-beam 110b is located to detect any protruding substrate. In FIG. 10A, substrate 104 is not protruding and therefore does not break sub-beam 110b. In FIG. 10B, substrate 104 is protruding and breaks sub-beam 110b as door 102 moves in the Z direction to scan along the opened substrate container. One skilled in the art will appreciate that the location of sub-beam 110b is dependent on the application and the acceptable amount of protrusion tolerated by the system. Thus, sub-beam 110b can be located to detect various protrusions by adjusting the location of the corresponding beam splitter and sensor of arms 100a and 100b.

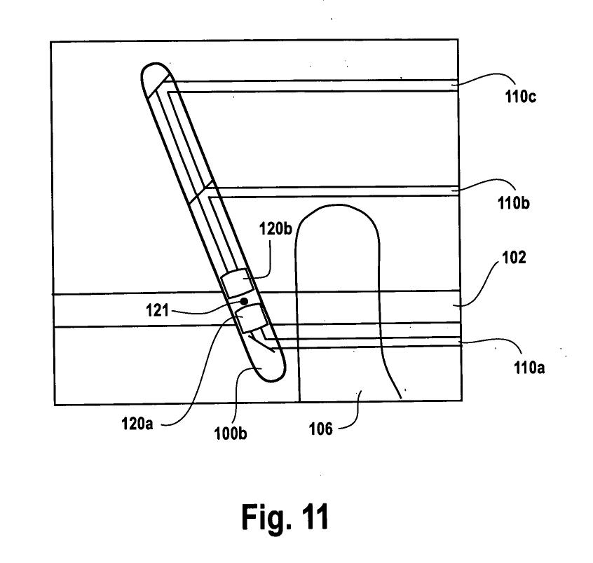

FIG. 11 is a simplified schematic diagram illustrating an alternative emitter assembly for the detection system in accordance with one embodiment of the invention. Here arm 100b extends over both sides of door 102 as a result of pivoting around pivot point 121. In this embodiment, multiple emitters 120a and 120b are provided. Sub-beam 110a is located on an opposing side of door 102 from sub-beams 110b and 110c. Arm 100a, while not illustrated, would be similarly configured to accept or reflect the corresponding sub-beams from arm 100b. It should be noted that arm extensions 100a and 100b are situated so as to provide enough clearance for end effector 106 to move therebetween. The embodiments described herein may be extended to include a single detector, e.g., a linear CCD imaging array or a two axis imaging array, e.g., a CCD having an XY array.

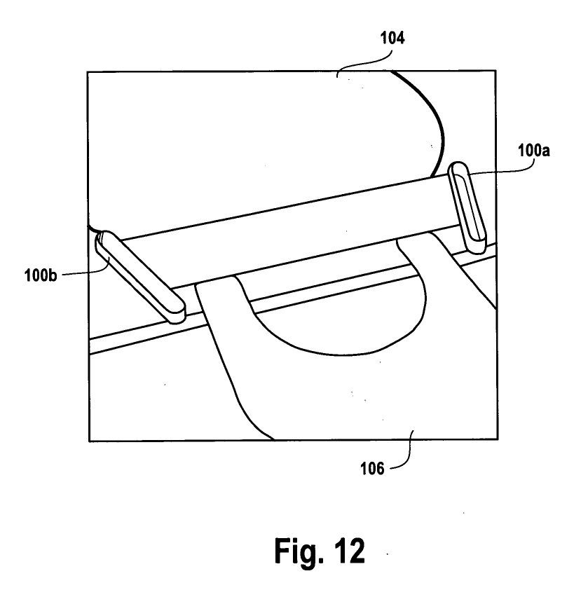

FIG. 12 is a simplified schematic diagram illustrating an illumination source that generates a plane of illumination in accordance with one embodiment of the invention. In one embodiment, illumination plane 123 may be generated by a laser beam intersecting a glass rod at 90 degrees to the rods axis. The detector of arm extension 100a is a device that has many sensors, e.g., a linear CCD sensor, in order to detect which part of the plane of illumination is broken. The embodiment of FIG. 12 permits a more precise measurement of the amount of protrusion of the substrate from the substrate carrier, as well as the previous mentioned measurements. In addition, the position of the end of end effector 106 is measured in a direction parallel to the substrate's surface. The aperture of the detector is a linear slot, as well as the aperture inside of arm 100a, in this embodiment. One skilled in the art will appreciate that the line scan may be mechanically generated, e.g., by a rotating mirror assembly located within the arm assembly. Alternatively, the line emission may be replaced with a radial emission having a beam appearing more like a wedge shaped fan as opposed to a parallel beam. It should be appreciated that the emitter arm may include an aperture that is a slot instead of or in conjunction with a slot on the detector arm.

When an XY array pixel sensor is used, e.g., a camera chip, with a line emission source, a single line or a small set of adjacent parallel lines of pixels will be illuminated by the emission when no substrate is interrupting the beam. For a beam (or a beam/aperture) that is smaller in diameter than the substrate thickness, there will be a time when no pixels will be illuminated by the emission source until the substrate clears the beam. For a substrate which is tilted at a slight angle from the horizontal plane, as the highest point of the surface intercepts the beam, a portion of the beam will be reflected onto pixels above the normally illumined line or lines. The number of pixels above this normally illuminated line is a measure of the angle of the substrate tilt. At some point the entire beam, provided the beam thickness is less than the substrate thickness, is blocked and no pixels are illuminated. Continuing the scan in the minus Z direction, the substrate will clear the beam and the line or set of lines will be illuminated on the sensor again. This will repeat for each substrate in the carrier.

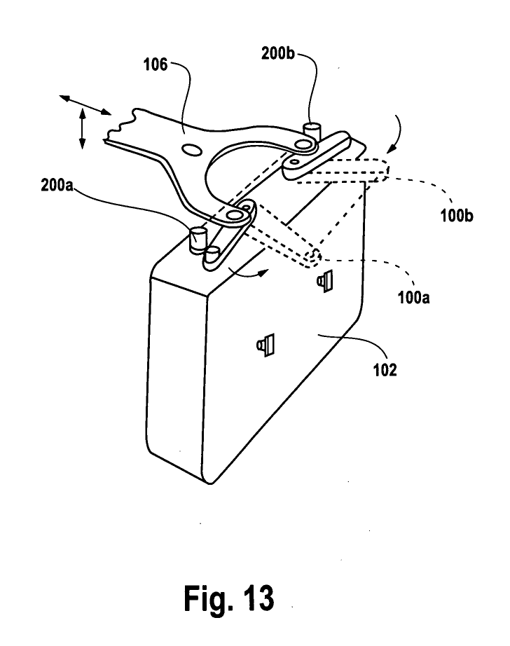

FIG. 13 is another embodiment that has the End Effector emitter and sensor mounted directly on the door assembly. In this embodiment, a wider end effector may be used with the pivotable arms for the end effector sensor. Pivotable arms 100a and 100b are provided to generate the sub-beams for the protrusion detection and the top and bottom surfaces of the substrates in the carrier. Sensor pair 200a and 200b are provided for mapping the tip of end effector 106 relative to the position of the substrate top and bottom surfaces as described herein.

In another embodiment, the emitter/sensor assembly is mounted separately from the door and is used to scan the carrier of substrates. In another embodiment, the emitter/sensor assembly is fixed in Z while the carrier is moved in Z to perform the scanning. In yet another embodiment, both the emitter/sensor assembly is a linear array in the Z direction that is moved into position inside a carrier and then remains stationary during the scan. This embodiment permits active measurement of the substrate and end effector without moving the door in the Z direction. In addition, this embodiment permits active detection of the presence, removal, or insertion of any substrate in the carrier. In one embodiment, the analog processing electronics are contained within the arm assemblies for both emission and detection. One skilled in the art will appreciate that this embodiment improves signal to noise ratio by eliminating the need for analog signals to be routed through long distances of cables from the emitter or detector to an external signal processing electronics board. In another embodiment, a filter with a pass band of the wavelength of the emitter is placed in front of the detector improving the signal to noise ratio which would be degraded by ambient or other forms of light illuminating the detector.

In still yet another embodiment, the emitter is modulated in amplitude and/or frequency with the detector appropriately demodulated to improve the signal to noise ratio when the detector is illuminated with a source of a different frequency. For example, room light generated by fluorescent lamps varies at 2× the line frequency. For a 60 Hz AC voltage system, this is 120 Hz in frequency. An emitter/detector system modulated at 40 KHz is immune to the effects of 60 Hz interference, improving the signal to noise ratio. In an alternative embodiment, a camera (or several cameras) is used to take a picture of the substrates and end effector whose positional information can be determined based on the measurements from the recorded image, through image processing techniques. For example, in one embodiment, a stereo picture pair is taken, allowing the measurements to be taken from the recorded image.

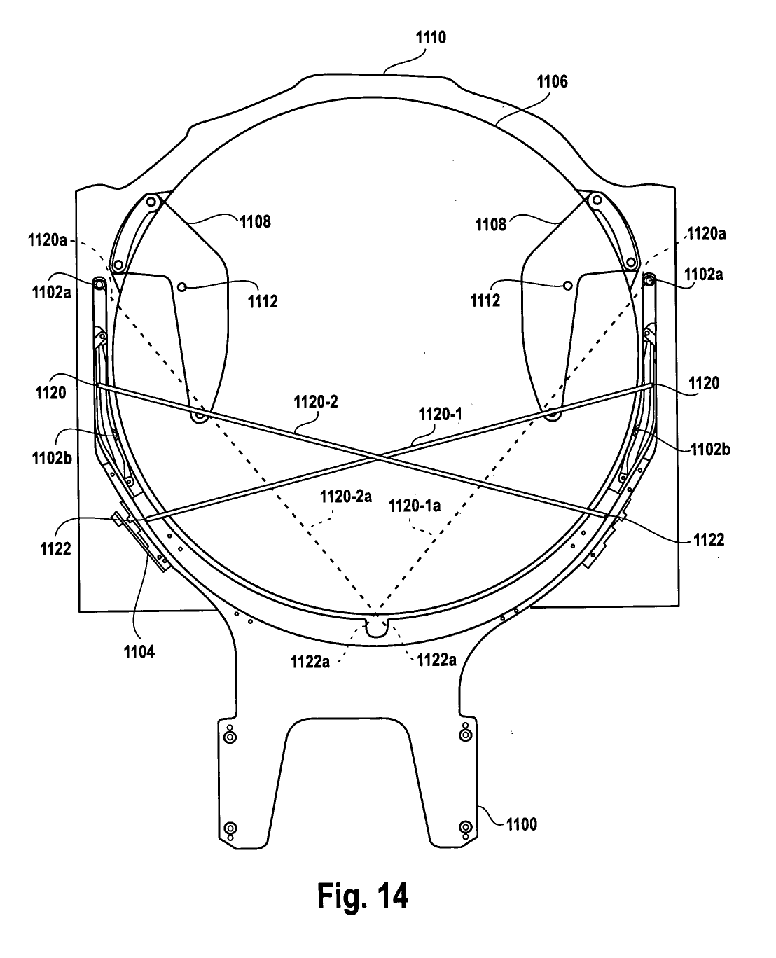

The embodiments of FIGS. 14-28 illustrate an external end effector and internal end effector having sensing capabilities to further enhance mapping and placement of wafers within a Front opening Unified Pod (FOUP) in accordance with one embodiment of the invention. In the embodiments described below, the sensing capabilities provide for measuring offset/position of a wafer within a FOUP and/or the support arms of the FOUP which support the wafer. It should be appreciated that the position attributes of the wafer as well as the wafer and the supports can be calibrated or compensated for when the FOUP is filled with the corresponding wafers. With regard to calibrating or sensing the positions of the supports alone, the wafer container will be scanned without wafers. The embodiments described herein further provide for devices which emit a beam and have corresponding receivers to detect whether the beam has been broken or not in one embodiment. In another embodiment, the beam emitted has a vertical height or horizontal width associated with it and the receiver may be an array of receivers capable of discriminating where a shadow is cast on the beam column. One skilled in the art will appreciate that while the sensors described herein are break-the-beam sensors in some embodiments, the embodiments described below are not limited to a break-the-beam sensor. In one embodiment, an image capture device, e.g., a complimentary oxide semiconductor (CMOS) chip or charge coupled device (CCD), may capture an image representative of the wafer holding container with or without wafers. The image may then be used to provide the positional attributes.

FIG. 14 is a simplified schematic diagram illustrating an external end effector having sensing capabilities according to one embodiment of the invention. End effector 1100 is inserted into front opening unified pod (FOUP) 1110 and is in a position to lift a corresponding wafer 1106 from the FOUP. End effector 1100 includes extensions which encompass a portion of wafer 1106 when inserted into FOUP 1110. End effector 1100 also includes support pads 1102a and 1102b on corresponding arm extensions of the end effector. In one embodiment, support pads 1102a and 1102b are pivoted into a position underneath wafer 1106 in order to support wafer 1106 for transportation into and out of FOUP 1110. A lever mechanism controlled through actuator 104 may trigger the pivoting of support pads 1102a and 1102b in one embodiment. FOUP 1110 includes support arms 108, which maybe cantilevered and have support pads 1112 disposed thereon to support corresponding wafers. End effector 1100 is equipped with sensing capabilities in the embodiment described herein. For example, sensor 1120 may be configured to detect a beam of light or photons which are generated by emitters 1122. Sensor 1120 may be placed at any position along the arm extensions of end effector 1100. It should be appreciated that the positions described herein are not meant to be limiting and are only exemplary. Sensor 1120 is provided in one exemplary position with corresponding emitter 1122 and provides a beam pattern illustrated by beams 1120-1 and beam 1120-2. In this pattern, the beam pattern provided by beams 1120-1 and 1120-2 may be referred to as a shallow X. The pattern provided by sensor 1120a and emitters 1122a through beams 1120-1a and 1120-2a form a V pattern. In addition to placing sensor 1120 at multiple positions, as well as the corresponding emitters 1122, multiple emitters and sensors may be placed on a single end effector 1100. As illustrated in FIG. 1, beams 1120-1, 11120-1a, 1120-2 and 1120-2a will intersect a corresponding support arm 1108 in order to determine or calibrate the movement of a corresponding wafer into and out of FOUP 1110. The sensing capabilities may also be extended to detecting any tilt or offset associated with support arms 1108.

In one embodiment, FOUP 1110 can be scanned by vertically moving end effector 1100 along a Z axis, while the end effector is placed between wafers 106 and the container walls of FOUP 1110. It should be appreciated that external end effector 1100 with active edge region supporting flippers or posts 1102a and 102b can move outside of the perimeter of the wafers while the wafers are disposed inside of FOUP 1110. Through the sensing provided herein, any tilting or offset can be detected and adjustments may be made in order to prevent any wafer damage as well as place the wafer into FOUP 1110 to minimize particulate generation and wafer damage. In addition, the sensing capabilities may be utilized to determine a center point of the wafer being supported which may be utilized in other downstream processes. Rather than using a single beam which may be intersecting both support arms 108, the embodiments described herein provide for a beam intersecting a single support arm so that information relevant to the corresponding support arm may be gathered without any ambiguity. That is, if one of a pair of support arms 1108 is offset or tilted, the beam corresponding to that support arm will expose this and there will not be any ambiguity, as opposed to when a single beam which is used for both support arms. In one embodiment, the beam may be a light beam from a light emitting diode (LED), a laser diode, etc., and may have a finite diameter. For example, the beam may have a 10-15 mm diameter in one embodiment. The array of sensors can then track an R position of the wafer, where the edge of the wafer is relative to the position of the end effector. The shadow of the beam may represent or be demarcated on the sensor array in order to provide information on the orientation and position of the wafer within FOUP 1110. It should be appreciated that with the embodiments described herein, the notch of the wafer will not have any impact on the sensing capabilities. In one embodiment, the data provided through the sensing can also be used to determine how deep to set a wafer into a corresponding FOUP without hitting a backstop of the FOUP. It should be appreciated that this sensing can be formed by looking at a leading edge of the wafer when the wafer is set in the FOUP or by scanning an empty FOUP when looking at the back section of the FOUP where the stop is located.

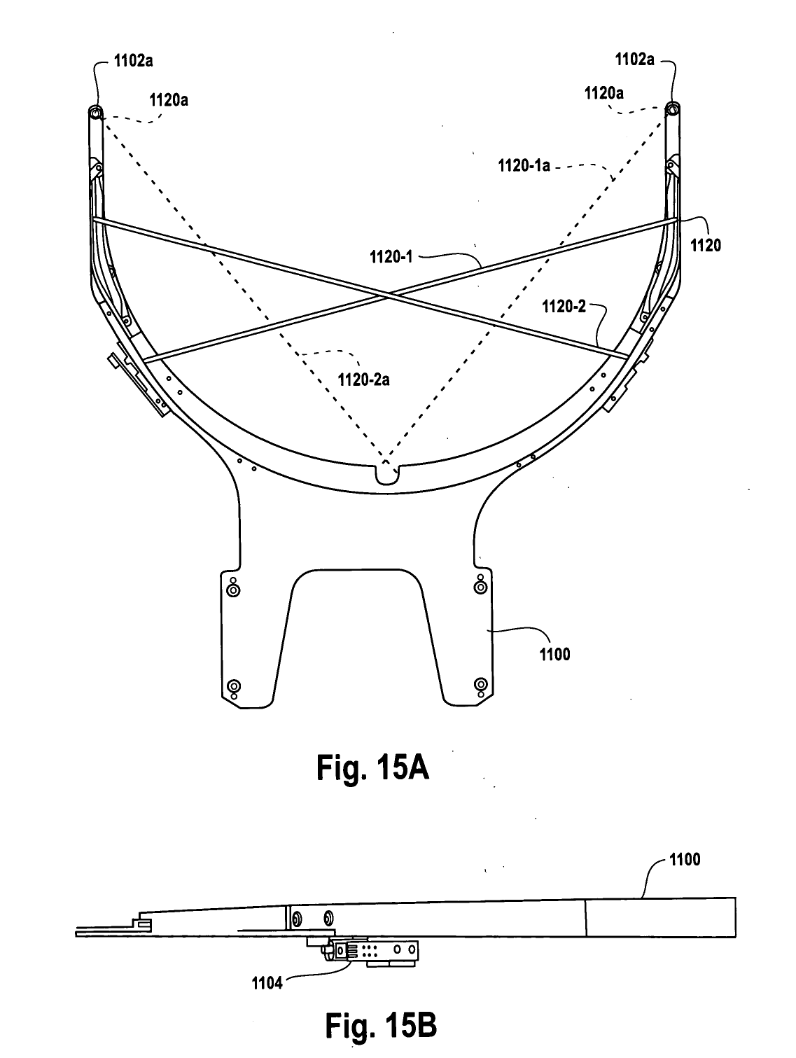

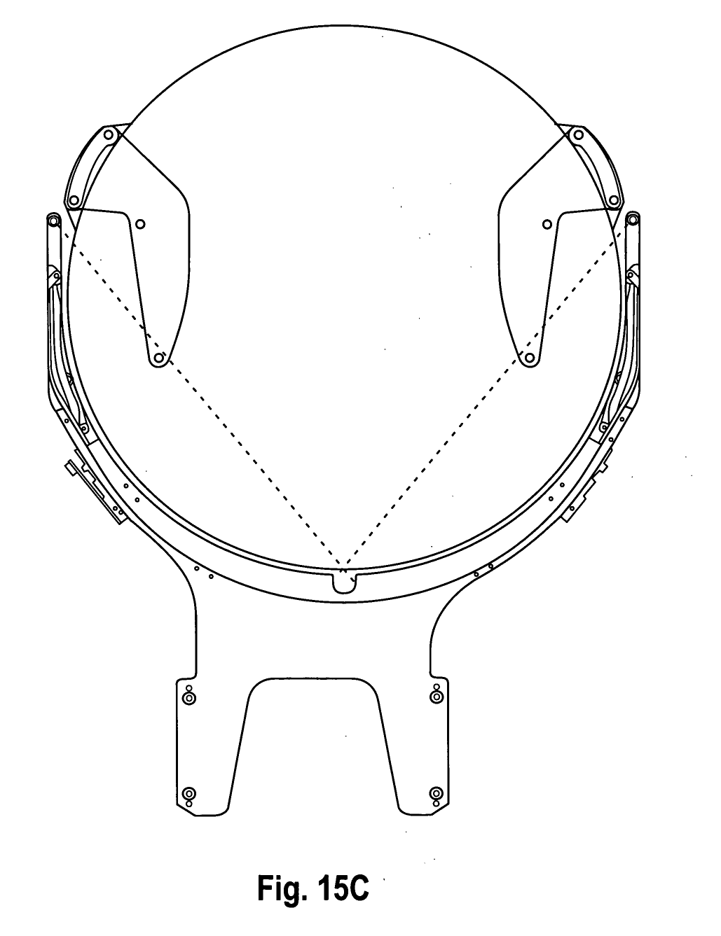

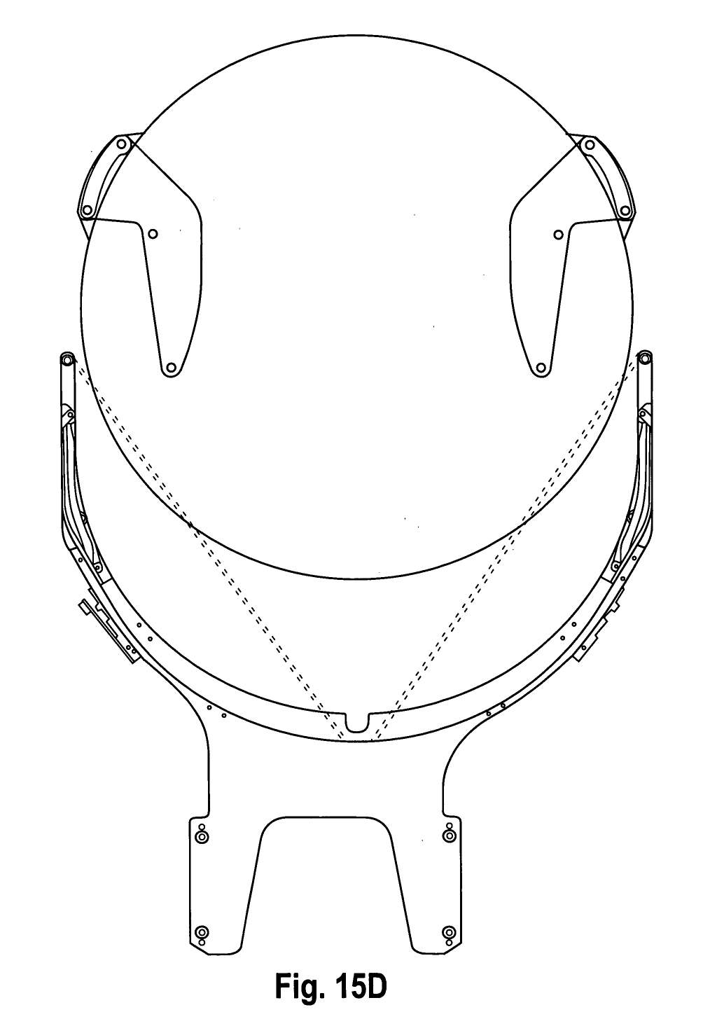

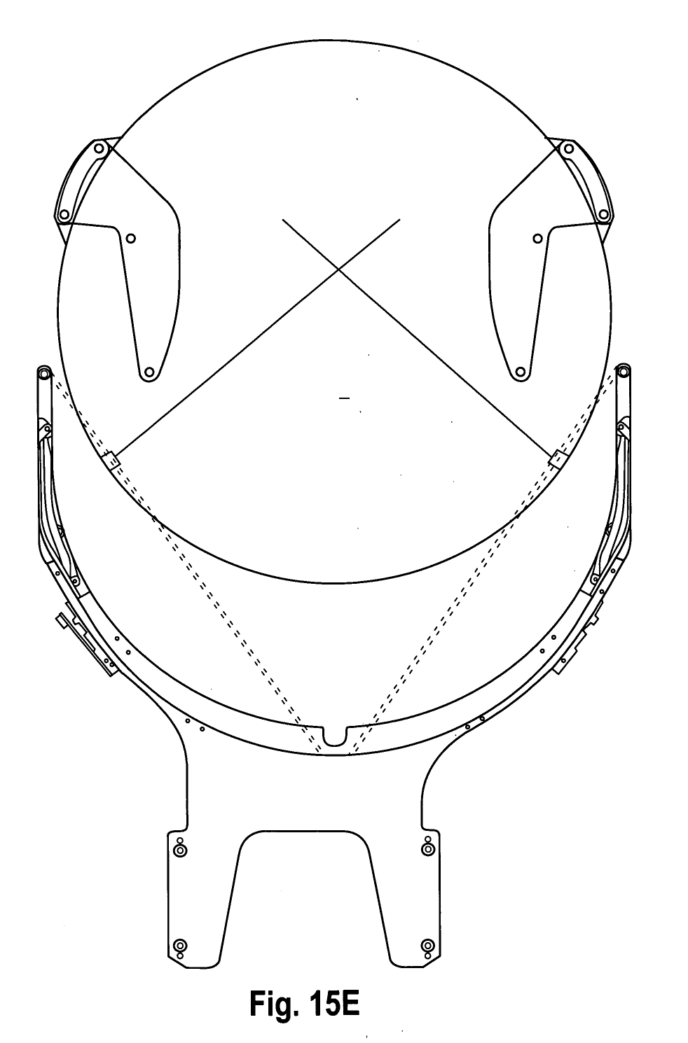

FIG. 15A is a simplified schematic diagram illustrating the end effector with sensing capabilities in accordance with one embodiment of the invention. External end effector 1100 includes support stops 1102a on corresponding arm extensions of the end effector. Sensor 1120 is provided so that a beam may be detected from the corresponding semitters 1122. As mentioned above, sensor 1120 may be positioned at numerous locations along the arm extensions of end effector 1100, dependent upon the application and data desired.

FIG. 15B is a simplified schematic diagram of a side view of the end effector in accordance with one embodiment of the invention. Actuator 1104 is provided underneath a bottom surface of end effector 1100 and is used to actuate or flip or even slide support stops 1120a and 1120b.

FIGS. 15C and 15D are simplified schematic diagrams illustrating the end effector positioned at different locations relative to the wafers to generate different positional information in accordance with one embodiment of the invention. In FIG. 2C the position of the support arms is being detected. This embodiment shows the optical beams going from the center of the back of the end effector to the tips of the end effector in a “V” beam. In this case the detector would be in the stationary part of the end effector tip below the moving support arm.

In FIG. 15D the position of the wafer edge, e.g., to determine deflection or tilting at the edge, is detected. The determination of these positional attributes can be stored and used to adjust movement of the end effector in one embodiment. In this embodiment, the “V” beam used to map the 2 front edges of the wafer in the areas of most concern. Wafer tilt or warp could be known this way besides wafer presence.

FIG. 15E is a simplified schematic diagram of utilization of the sensing capability of the end effector to determine a position of the center of the substrate in accordance one embodiment of the invention. In this embodiment, the tip may have a horizontal linear array of sensors to detect the light beam from the back end of the end effector. In one embodiment, the beam is 6 mm wide. The end effector would vertically scan and record the maximum shadow cast on the sensor for each side. This gives 2 tangent points for the wafer, and knowing the diameter of the wafer and the angle of the beams, the center point of the wafer could be calculated. It should be appreciated that variations in wafer diameter would cause small center errors, but silicon wafer diameters are controlled to a tight tolerance.

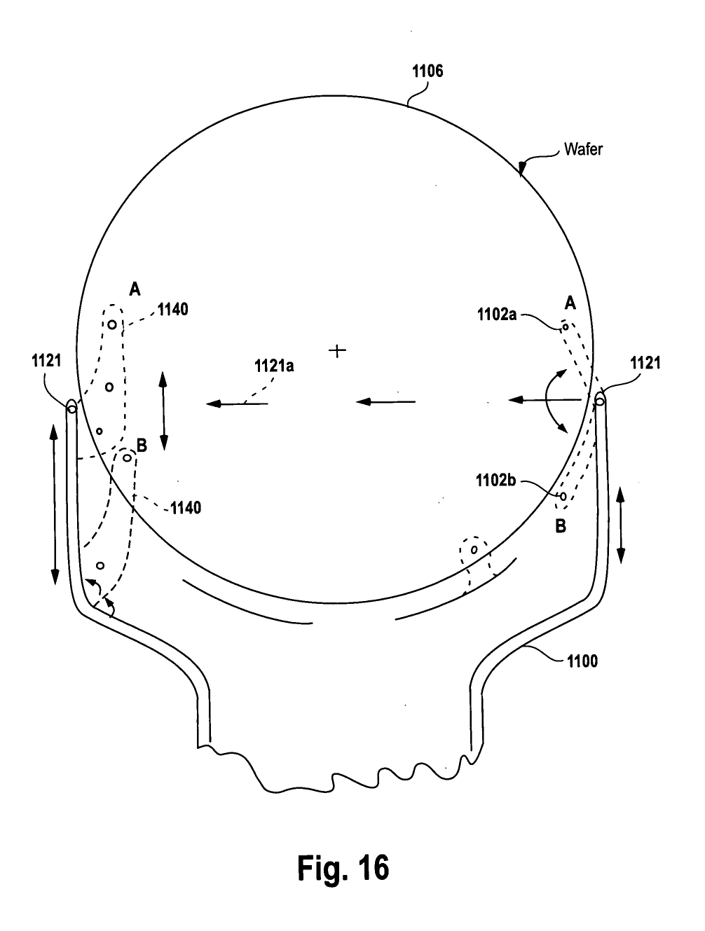

FIG. 16 is a simplified schematic diagram illustrating alternative versions of the end effector with sensing capabilities in accordance with one embodiment of the invention. End effector 1100 includes a first support arm having support stops 1102a and 1102b which flip or rotate underneath wafer 1106. Alternatively, end effector 1100 may include support stops that slide along the arm extension of the end effector. In FIG. 16, support stops on chassis 1140 are located at two different positions as illustrated by 1140-1 and 1140-2. In the position illustrated by 1140-1 the support stop has been retracted in order for sensor 1121 to perform some sensing as desired. In order to lift or transport wafer 1106, support stop at position 1140-1 is transitioned to position A. Thus, in one embodiment, a linear slide and actuator means is provided in order to move the support stops, while in a second embodiment, a pivoting arm is used to move the support stops so that the end effector can move between wafers 1106 and a container wall of the FOUP to vertically scan the wafer stack within an FOUP.

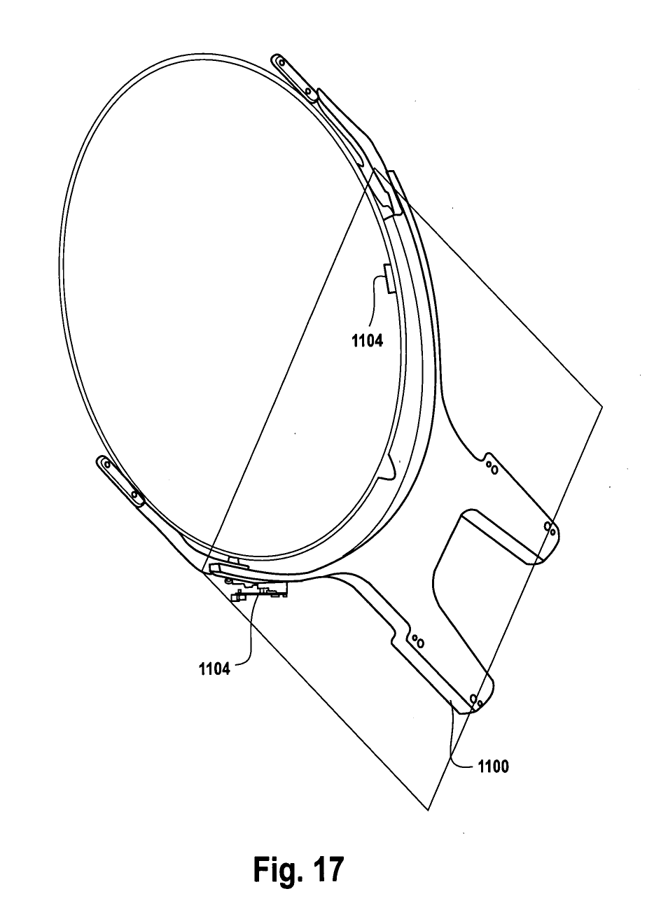

FIG. 17 is a simplified schematic diagram illustrating a perspective view of the end effector in accordance with one embodiment of the invention. End effector 1100 includes actuator means 1104 which provide pivotable movement for support stops used to support a corresponding wafer. It should be appreciated in an alternative embodiment actuator means 1104 may provide the slideable mechanism to move the support stop along a linear slide.

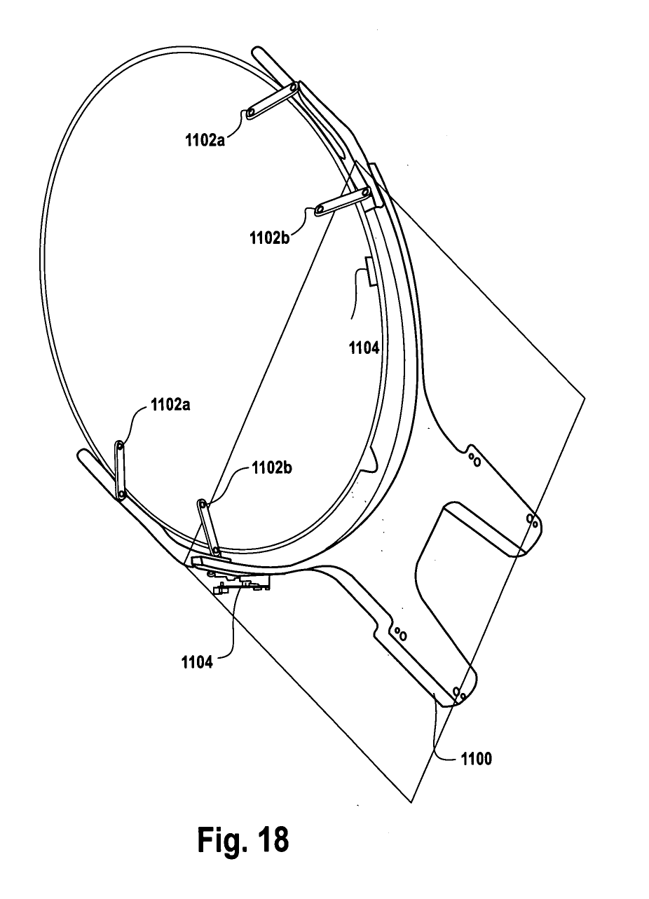

FIG. 18 is a simplified schematic diagram of the end effector with the pivoted supports actuated in accordance with one embodiment of the invention. End effector 1100 through actuator means 1104 has triggered support stops 1102a and 1102b to move or pivot into position to support a corresponding wafer. One skilled in the art will appreciate that in one embodiment the support stops 1102a and 1102b are in an actuated or supporting mode when power is lost so that a wafer is not damaged when power is lost.

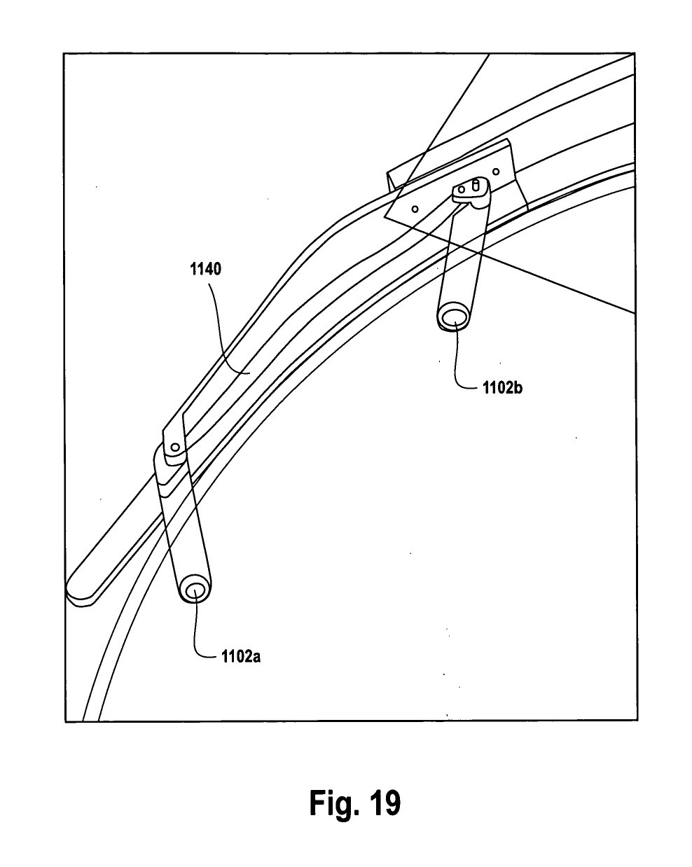

FIG. 19 is a simplified schematic diagram showing further details on the pivotable mechanism triggered in order to actuate support stops 1102a and 1102b. The end effector arm extension includes a connector arm 1140 which connects to the supporting structure for support stops 1102a and 1102b. When a mechanism such as actuator 1104 of FIGS. 4 and 5 is triggered, then control arm 1140 will move such that support stops 1102a and 1102b pivot around a corresponding pivot point. In one embodiment, support stops 1102a and 1102b are raised members on the pivotable support stop extension.

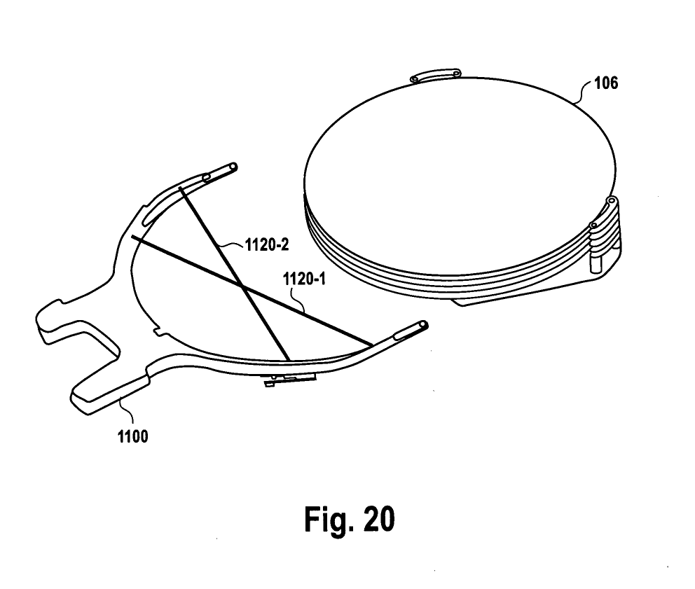

FIG. 20 is a simplified schematic diagram illustrating an end effector having sensing capabilities in accordance with one embodiment of the invention. End effector 1100 is positioned to enter a corresponding FOUP holding wafers 1106. It should be appreciated that the outer container walls of the FOUP have been cut away in order to provide a clear illustration. End effector 1100 has sensing capabilities which provide beams 1120-1 and 1120-2. End effector 1100 can move into position around wafers 1106 and provide information on the location tilt, position, etc. of the wafers through the sensing beams provided.

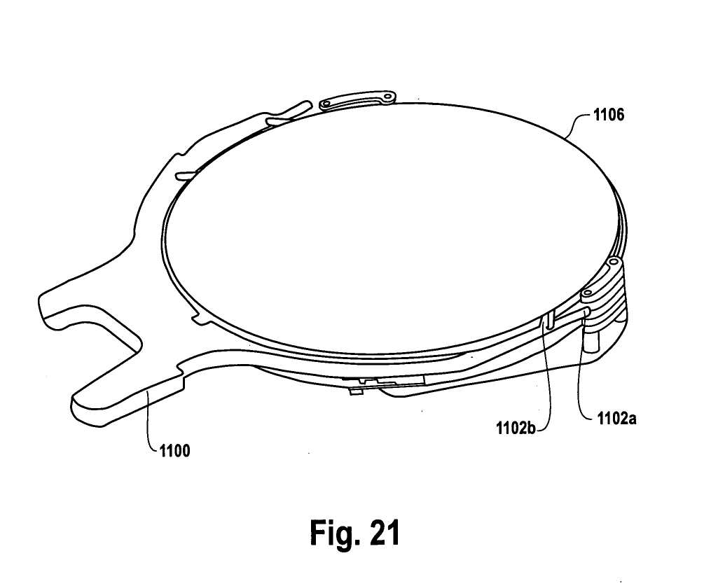

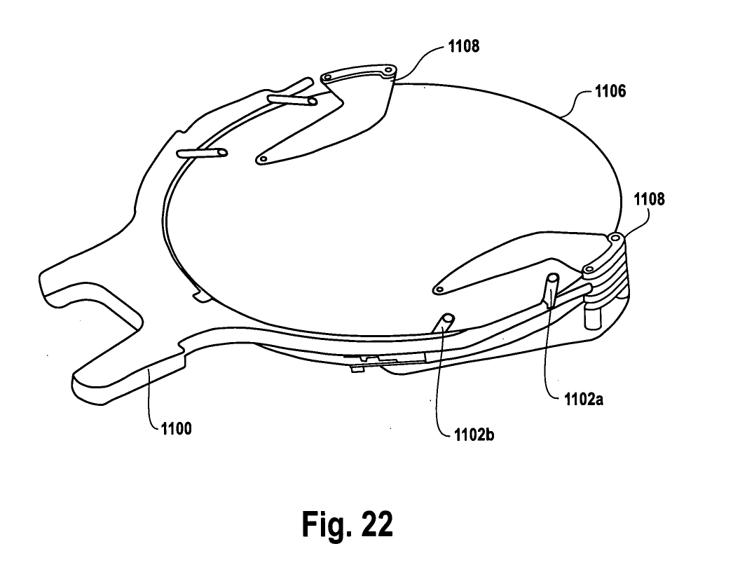

FIG. 21 illustrates end effector 1100 moved into position around wafer 1106 in accordance with one embodiment of the invention. Once end effector 1100 has been moved around the corresponding wafers, support stops 1102a and 102b may be triggered to pivot in order to capture a corresponding wafer for support and transportation. FIG. 22 illustrates end effector 1100 having actuated support stops 1102a and 1102b. In FIG. 22, the top wafer has been removed in order for illustrated purposes.

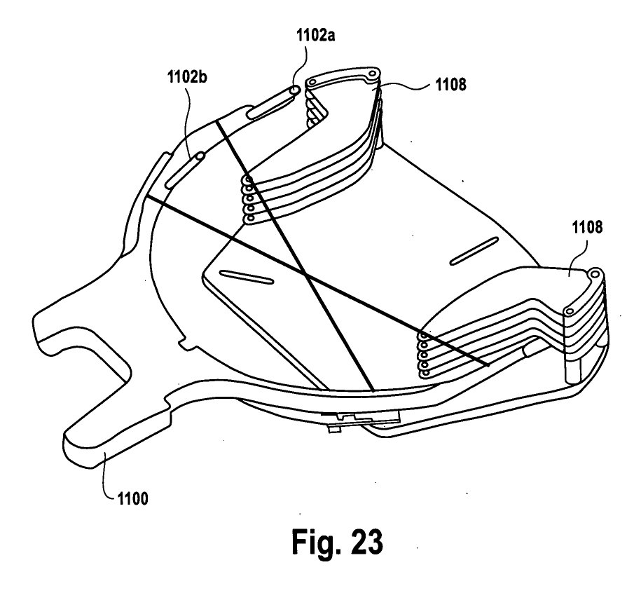

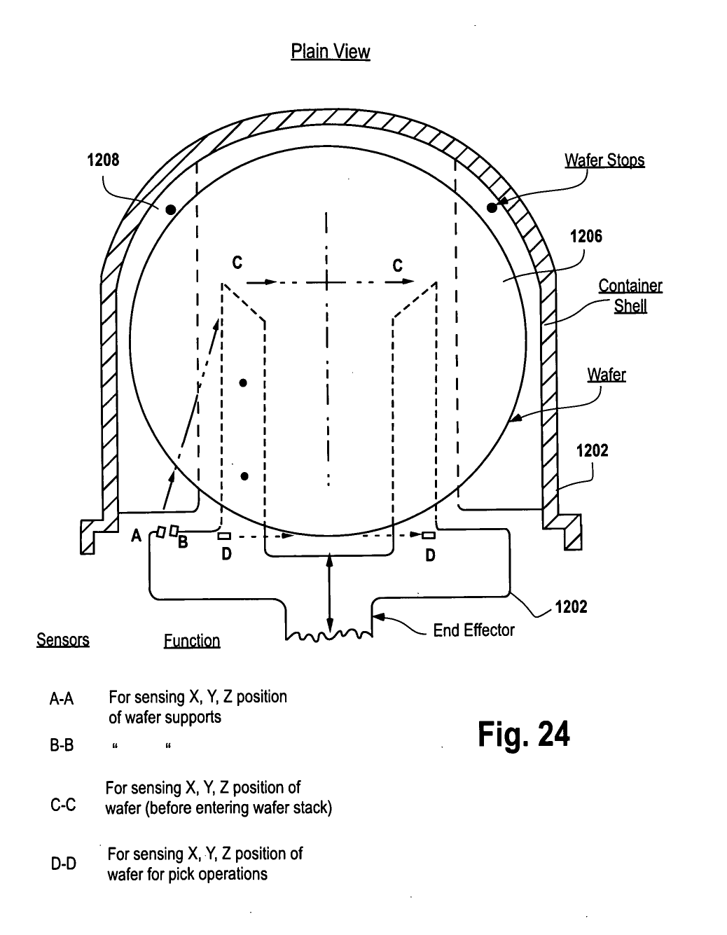

FIG. 23 is a simplified schematic diagram illustrating the end effector in position with an empty FOUP in accordance with one embodiment of the invention. End effector 1100 is illustrated engaged with a corresponding FOUP. The FOUP has the container walls removed in FIG. 23 for illustrative purposes. As described above, the sensing capabilities of end effector 1100 will provide information on the relative location of the support arms 1108. That is, if the support arms are offset or tilted, the sensing capabilities provided through end effector 1100 will detect this and adjustments may be made for the pickup and drop off of corresponding wafers. As mentioned above, the sensors and emitters may be placed at numerous locations on the end effector arms top provide alternative beam patterns and associated data. It should be appreciated that FIGS. 14 through 23 provide illustrations directed toward an external end effector. However, in an alternative embodiment sensing capabilities may be provided through an internal end effector as described with regard to FIGS. 24-27.

FIG. 24 illustrates a simplified schematic diagram of an internal end effector having sensing capabilities in accordance of one embodiment of the invention. End effector 1200 is configured to enter a FOUP between support walls 1208. The end effector and its arm extensions which proceed into the FOUP has sensors mounted in order to sense certain locations. For example, sensor path A-A will sense the XYZ position of the wafer supports. Sensor path B-B will also sense the XYZ positions of wafer supports 1208. Sensor path C-C may be used for sensing Y and Z position of the wafer prior to entering the FOUP. It should be appreciated that if sensor path C-C is used to scan the outer periphery of the wafers prior to inserting the arm extensions into the FOUP, the Y and Z positions of the corresponding wafers may be captured. Sensors D-D may be used for sensing the YZ position of the wafer for pickup operations in accordance with one embodiment. The data from the sensors may be manipulated through a special purpose computer and stored for later use of position adjustment of the end effector.

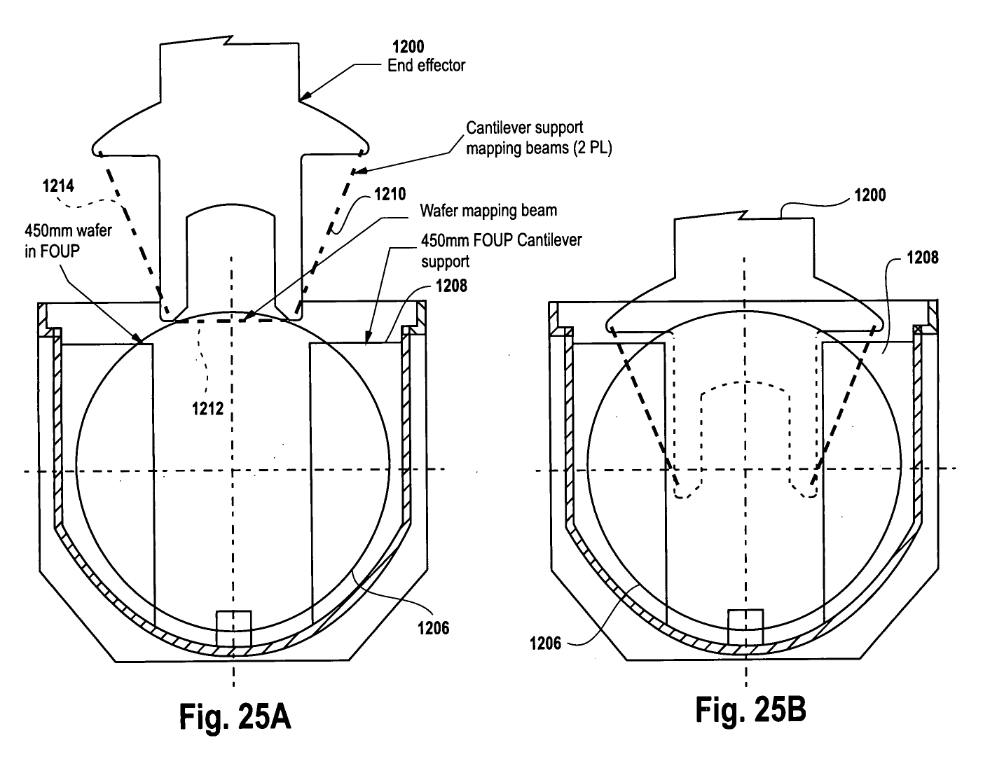

FIGS. 25A and 25B illustrate an internal end effector and corresponding FOUP with the end effector prior to entry into the FOUP in FIG. 25A and inserted into the FOUP in FIG. 25B. End effector 1200 is illustrated as capable of generating sensing beams 1210, 1212, and 1214. The sensing beams, also referred to as wafer mapping beams, are similar to the beams described above in FIG. 24. These beams may be utilized to map the wafers 1206 prior to entry into the FOUP by the end effector 200 as illustrated in FIG. 25A. In addition, the orientation or positional information for the support walls of FOUP are provided through wafer mapping beams 1210 and 1214 when inserted into the FOUP as illustrated in FIG. 25B.

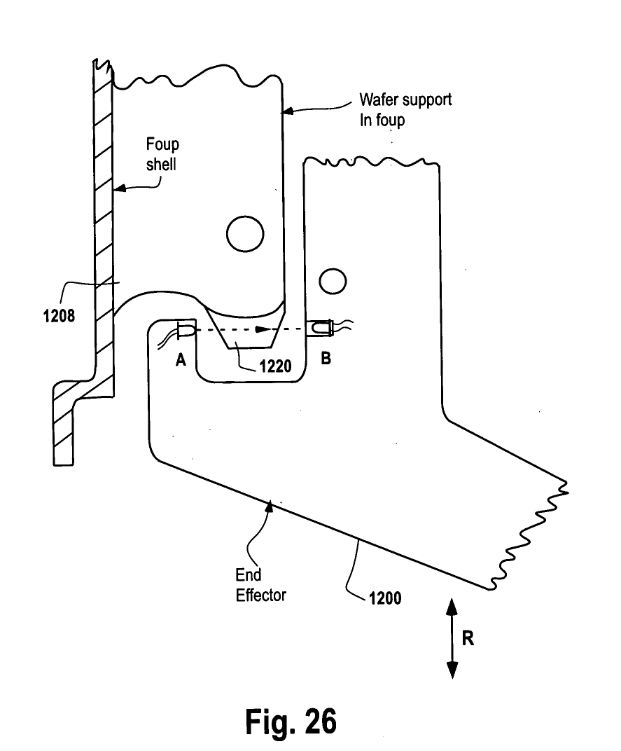

FIG. 26 is a simplified schematic diagram of an alternative embodiment for an internal end effector sensing capability. End effector 1200 is inserted into a corresponding FOUP. Supports 1208 within the FOUP have extensions 1220 which can be used so that a beam will be broken between sensors A and B. Thus, in an empty FOUP the end effector 1200 can scan the corresponding supports 1208. In addition, support extensions 1220 may be used to gauge how deep to place a corresponding wafer into the FOUP in order to not hit a backstop and generate particles. That is, sensor pair AB may sense the extension 1220 and based on the sensing of that extension, may gauge a depth for setting the wafer into the corresponding FOUP.

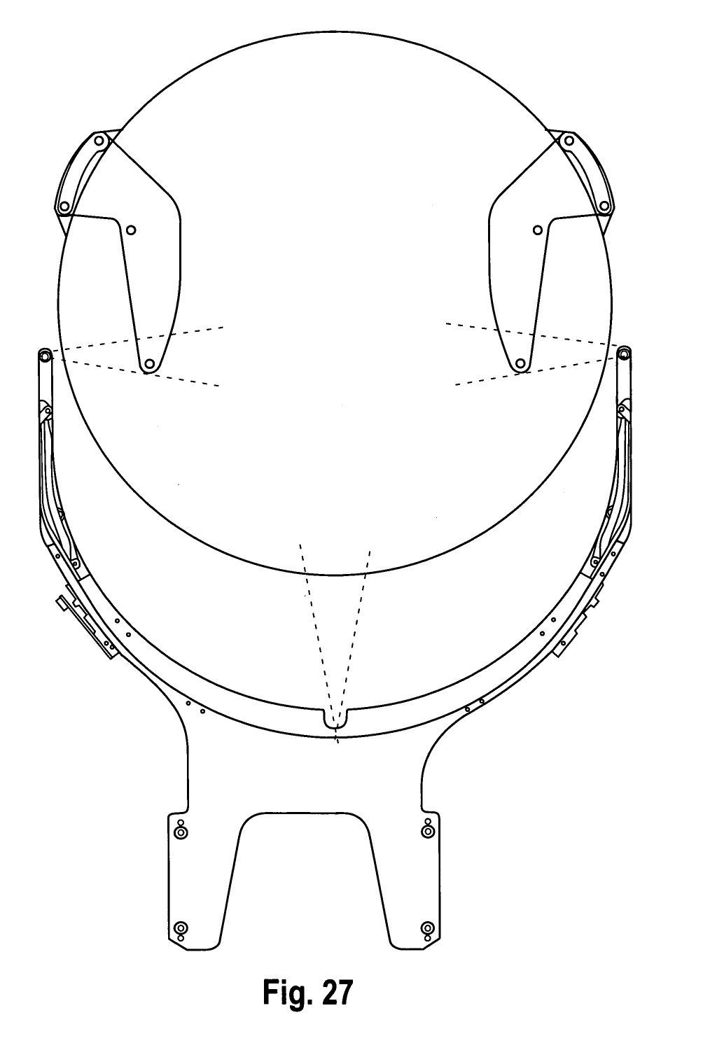

FIG. 27 is a simplified schematic diagram of the use of image capture devices providing the sensing capabilities of the end effector in accordance with one embodiment of the invention. It should be appreciated that while the image capture devices are illustrated with an external end effector, the image capture devices may also be integrated with an internal end effector. The CCD/CMOS image sensors may be placed at the tips of the end effector or the back of the end effector to view images of the wafer edge and possibly the FOUP wafer supports. The CCDs could be used in conjunction with light sources or alternatively, the image capture devices could use ambient light. In one embodiment, the end effector can slowly scan the wafers. Alternatively, the end effector can move to discrete locations and stitch the resulting images together to generate an overall view.

In should be appreciated that when a wafer is placed on an end effector it is imperative that proper placement of the wafer can be sensed. Previous generations of wafer handling end effectors used vacuum gripping or edge gripping of the wafer. In the case of vacuum gripping, proper placement was sensed if the vacuum level in the orifice dropped to an adequately low pressure, signaling that the wafer was properly seated and sealing the vacuum orifice. In the case of edge grip, the plunger that pushes the wafer has the capability to sense the plunger positions. Too much plunger motion signals that the wafer is not gripped between the plunger and the passive tips. Too little motion signals that the wafer or mechanism is somehow stuck.

It is desirable to minimize forces on the back and edge of the 450 mm wafer so forceful edge grip or strong vacuum gripping is not recommended. Gripping of the wafer will more often depend on the friction between the end effector support pads and the backside wafer surface. In this case wafer presence still must be sensed. There are several ways that this could be done.

Thin capacitive sensing elements could be mounted on the top surface of the end effector near the support pads. The capacitive sensors could have the added capability of sensing the relative distance to the wafer as the end effector moves upward to pick up the wafer, allowing for compensation in the end effectors upward movement to adjust the final position for the optimum wafer clearance during retraction. The capacitive sensor could be next to the support pad and a small distance lower to assure that the wafer contacts the pad, or the capacitive sensor could be integrated into the pad itself having its top surface made of the appropriate contact material. Capacitive sensors are made by having 2 flat electrode surfaces in the same plane and near each other. A first electrode is driven with an alternating voltage, usually at a frequency of several KHz. A coupled signal is measured on the second electrode. When a wafer, which has a reasonable conductivity, is placed in proximity to the plane of the electrodes, the capacitive coupling between the 2 electrodes increases and the coupled signal on the second electrode increases. The level of signal increase can be used to determine the distance to the wafer.

A low level of vacuum could be used to measure wafer presence. This is similar to what is used for vacuum gripping but the vacuum level is substantially reduced to minimize distorting forces on the backside of the wafer. This reduced vacuum is not enough to provide substantial gripping force but is still adequate to measure wafer presence. When the wafer is properly seated, the vacuum orifice is sealed and pressure drops.

Air pressure could be used for sensing. A low flow of clean air could be forced out through orifices in the end effector pads. When the wafer is properly placed on the end effector pads, the orifices would be blocked and the subsequent back pressure could be sensed.

Force or strain gauges could be used. The support pad could be mounted with a small cantilevered member and allowed to deflect a small amount when supporting the weight of the wafer. The force or strain gauge mounted at the base of the cantilevered member would detect the bending of the cantilevered member and signal that the wafer is properly placed on the pad.

Embodiments of the present invention may be practiced with various computer system configurations including hand-held devices, microprocessor systems, microprocessor-based or programmable consumer electronics, minicomputers, mainframe computers and the like. The invention can also be practiced in distributed computing environments where tasks are performed by remote processing devices that are linked through a wire-based or wireless network.

With the above embodiments in mind, it should be understood that the invention can employ various computer-implemented operations involving data stored in computer systems. These operations are those requiring physical manipulation of physical quantities. Usually, though not necessarily, these quantities take the form of electrical or magnetic signals capable of being stored, transferred, combined, compared and otherwise manipulated.

Any of the operations described herein that form part of the invention are useful machine operations. The invention also relates to a device or an apparatus for performing these operations. The apparatus can be specially constructed for the required purpose, or the apparatus can be a general-purpose computer selectively activated or configured by a computer program stored in the computer. In particular, various general-purpose machines can be used with computer programs written in accordance with the teachings herein, or it may be more convenient to construct a more specialized apparatus to perform the required operations.

The invention can also be embodied as computer readable code on a computer readable medium. The computer readable medium is any data storage device that can store data, which can be thereafter be read by a computer system. Examples of the computer readable medium include hard drives, network attached storage (NAS), read-only memory, random-access memory, CD-ROMs, CD-Rs, CD-RWs, magnetic tapes and other optical and non-optical data storage devices. The computer readable medium can also be distributed over a network-coupled computer system so that the computer readable code is stored and executed in a distributed fashion.

Although the method operations were described in a specific order, it should be understood that other housekeeping operations may be performed in between operations, or operations may be adjusted so that they occur at slightly different times, or may be distributed in a system which allows the occurrence of the processing operations at various intervals associated with the processing, as long as the processing of the overlay operations are performed in the desired way.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. A port door providing an interface into a processing tool, comprising:
first and second arms pivotably mounted on a top edge of the port door, the first and second arms configured to extend from a plane of the port door towards a carrier containing substrates for the processing tool, the first arm having an emitter transmitting a beam that is split into a plurality of sub-beams within the first arm, the second arm having a plurality of sensors receiving corresponding sub-beams, wherein one of sub-beams provides information as to a position of an end effector relative to a gap between the substrates in the carrier.

2. The port door of claim 1, wherein the port door moves in a plane normal to a processing surface of the substrates.

3. The port door of claim 1, wherein the first arm includes a plurality of semi-transparent mirrors along a travel path of the beam, the semi-transparent mirrors directing a portion of the beam to a corresponding sensor and a remaining portion of the beam to another semi-transparent mirror.

4. The port door of claim 1, wherein the first arm splits the beam into 3 sub-beams, the three sub-beams.

5. The port door of claim 4, wherein a first sub-beam detects a position of an end effector, a second sub-beam detects whether a substrate is protruding out of the carrier, and a third sub-beam detects positions of top and bottom surfaces of the substrates.

6. The port door of claim 1, wherein the first arm includes a plurality of sensors configured to detect a reflection of the sub-beams from the second arm.

7. A port door of a processing tool for interfacing with a substrate carrier, comprising:
a planar surface having a top edge;
first and second extensions pivotably mounted on the top edge, the first and second extensions configured to pivot towards the substrate carrier;
an emitter transmitting a beam along a length of the first extension;
a plurality of splitters serially disposed along the length of the first extension, each of the plurality of splitters redirecting a portion of the beam towards the second extension, wherein one of the redirected portions provides information as to a position of an end effector relative to a gap between substrates in the substrate carrier.

8. The port door of claim 7, wherein the first extension includes sensors configured to detect corresponding redirected portions after being reflected from reflectors disposed in the second extension.

9. The port door of claim 7, wherein the port door is integrated into a loadport and is configured to move in a direction substantially parallel to a z axis of the substrate carrier.

10. The port door of claim 7, wherein the second extension includes sensors for receiving each of the redirected portions.

11. The port door of claim 7, wherein a first redirected portion detects a position of an end effector, a second redirected portion detects whether a substrate is protruding out of the substrate carrier, and a third redirected portion detects positions of top and bottom surfaces of the substrates.

12. A method for transferring a substrate from a carrier, comprising:
positioning the carrier onto a carrier interface of a processing tool;
transitioning a door of the processing tool to allow transfer of the substrate, the transitioning including,
pivoting a first and a second extension toward the carrier;
generating a beam from an emitter disposed within the first extension;
splitting the beam into multiple sub-beams;
redirecting each sub-beam toward the second extension;
positioning an end effector to transfer a substrate from the carrier;
determining a position of the end effector relative to a position of the substrate through first and second sub-beams; and
adjusting the position of the end effector when the position of the end effector the position of the substrate coincide.

13. The method of claim 12, wherein the adjusting includes correcting a tilt of the end effector.

14. The method of claim 12, wherein the adjusting includes adjusting a vertical height of the end effector relative to the substrate.

15. The method of claim 12, further comprising;
moving the door of the processing tool substantially parallel to a vertical axis of the substrate carrier.

16. The method of claim 15, wherein the positioning the end effector occurs contemporaneously with moving the door of the processing tool.

17. The method of claim 12, wherein the transitioning includes,
reflecting each sub-beam to the first extension.

18. The method of claim 12, wherein the multiple sub-beams include a first sub-beam and a second sub-beam, the first sub-beam detects positions of a top and a bottom surface of the end effector along an axis substantially parallel to a vertical axis of the substrate carrier.

19. The method of claim 18, wherein the second sub-beam detects positions of a top and a bottom surface of the substrate along the axis.
